(19) United States
(12) Patent Application Publication
(10) Pub. No.: US 2016/0187282 A1
(43) Pub. Date: Jun. 30, 2016

(54) DEVICE FOR SINGLE MOLECULE DETECTION AND FABRICATION METHODS THEREOF

(71) Applicant: INTEL CORPORATION, Santa Clara, CA (US)

(72) Inventors: Donald S. Gardner, Los Altos, CA (US); Oguz H. Elibol, Sunnyvale, CA (US)

(21) Appl. No.: 14/583,373

(22) Filed: Dec. 26, 2014

(51) Int. Cl. G01N 27/30; C23C 16/02; H05K 3/30; G01N 27/49; C23C 16/32

(52) U.S. Cl. CPC G01N 27/308; G01N 27/49; C23C 16/325; H05K 3/303; C23C 16/02; H05K 2203/06

(57) ABSTRACT

Disclosed herein is a device comprising an electrode pair comprising a first electrode and a second electrode; a nanogap channel; wherein a portion of the nanogap channel is sandwiched between the first electrode and the second electrode; wherein at least a portion of the first electrode directly faces at least a portion of the second electrode, across the nanogap channel; wherein the portion of the first electrode and the portion of the second electrode are exposed to an interior of the nanogap channel; and wherein the first electrode or the second electrode comprises doped diamond, silicon carbide or a combination thereof. Also disclosed herein is a method comprising forming on a carrier substrate a first material layer comprising doped diamond, silicon carbide or a combination thereof; bonding the first material layer onto an electrical circuit.

### CROSS-REFERENCE TO RELATED APPLICATIONS

Reference is made to commonly owned and co-pending U.S. application Ser. No. 12/655,578 titled “Nanogap Chemical and Biochemical Sensors,” filed Dec. 31, 2009, now pending; U.S. patent application Ser. No. 11/226,696, titled “Sensor Arrays and Nucleic Acid Sequencing Applications,” filed Sep. 13, 2005, now pending; which is a continuation-in-part application that claims the benefit of U.S. patent application Ser. No. 11/073,160, titled “Sensor Arrays and Nucleic Acid Sequencing Applications,” filed Mar. 4, 2005; U.S. patent application Ser. No. 11/967,600, titled “Electronic Sensing for Nucleic Acid Sequencing,” filed Dec. 31, 2007 now pending; U.S. patent application Ser. No. 12/319,168, titled “Nucleic Acid Sequencing and Electronic Detection,” filed Dec. 31, 2008, now pending; U.S. patent application Ser. No. 12/459,309, titled “Chemically Induced Optical Signals and DNA Sequencing,” filed Jun. 30, 2009, now pending; U.S. patent application Ser. No. 12/655,459, titled “Solid-Phase Chelators and Electronic Biosensors,” filed Dec. 30, 2009, now pending; U.S. patent application Ser. No. 12/823,995, titled “Nucleotides and Oligonucleotides for Nucleic Acid Sequencing,” filed Jun. 25, 2010, now pending; U.S. patent application Ser. No. 12/860,462, titled “Nucleic Acid Sequencing,” filed Aug. 20, 2010, now pending; International Patent Application PCT/US2011/067520, titled “Nanogap Transducers with Selective Surface Immobilization Sites,” filed Dec. 28, 2011; International Patent Application PCT/US2011/065154, titled “Diamond Electrode Nanogap Transducers,” filed Dec. 15, 2011; and U.S. patent application Ser. No. 13/538,346, titled “High throughput biochemical detection using single molecule fingerprinting arrays,” filed on Jun. 29, 2012; the disclosures of which are incorporated herein by reference. Appropriate components for device/system/method/process aspects of the each of the foregoing patents and patent publications may be selected for the present disclosure in embodiments thereof.

### TECHNICAL FIELD

The present disclosure relates to a method for bonding doped diamond or silicon carbide to an electrical circuit. The method may be useful in fabricating a device suitable for single molecule detection and especially suitable for single molecule sequencing of molecules such as DNA, RNA, and peptides.

### BACKGROUND

Single-molecule sequencing enables molecules such as DNA, RNA, and peptides to be sequenced directly from biological samples without steps such as purification, separation, amplification of the molecules themselves. Single-molecule sequencing is thus well-suited for diagnostic and clinical applications.

The classical DNA sequencing technology (sometimes referred to as first generation sequencing technology) was developed in the late 1970s and evolved from a low-throughput approach, in which the same radiolabeled DNA sample was run on a gel with one lane for each nucleotide, to an automated method in which all four fluorescently labeled dye terminators for a single sample were loaded onto individual capillaries. These capillary-based instruments could handle hundreds of individual samples per week and were used in obtaining the first draft sequence of a human genome. Various improvements in components used in this technology pushed read lengths up to 1,000 base pairs (bp) without much improvement on the underlying principle.

The second generation sequencing technology emerged in 2005 and increases the throughput by at least two orders of magnitude over the first generation sequencing technology. Representative platforms include pyrosequencing (454 Life Sciences), Solexa (Illumina) and SOLiD (Applied Biosystems). The second generation sequencing technology is superior to its predecessor because the sequencing target changed from single clones or samples to many independent DNA fragments, enabling large sets of DNAs to be sequenced in parallel. Many platforms in this generation achieved massively parallel sequencing by imaging light emission from the sequenced DNA, or by detecting hydrogen ions (Ion Torrent by Life Technologies). The second generation sequencing technology avoids the bottleneck that resulted from the individual preparation of DNA templates required in the first generation technology. Read lengths of the second generation sequencing technology have exceeded 400 by at an error rate below 1%.

The second generation sequencing technology still requires amplification of template. Amplification may cause quantitative and qualitative artifacts that can have detrimental impacts on quantitative applications, such as chromatin immunoprecipitation sequencing (ChIP-Seq) and RNA/cDNA sequencing. Amplification also places limitations on the size of the template being sequenced because molecules that are too short or too long tend not to be amplified well.

The third generation sequencing technology allows sequencing one or a few copies of a molecule and thus is often referred to as the single-molecule sequencing technology. The third generation sequencing technology thus simplifies sample preparation, reduces sample mass requirements, and most importantly eliminates amplification of templates. The third generation sequencing technology tends to have high read lengths, low error rates and high throughput. The third generation sequencing technology allows resequencing the same molecule multiple times for improved accuracy and sequencing molecules that cannot be readily amplified, for example because of extremes of guanine-cytosine content, secondary structure, or other reasons. These characteristics of the third generation sequencing technology make it well suited for diagnostic and clinical applications.

The third generation sequencing technology encompasses a wide variety of platforms that differ in their fundamental principles. Representative platforms include sequencing by synthesis, optical sequencing and mapping, and nanopores.

### Sequencing by Synthesis

One representative sequencing-by-synthesis platform involves hybridizing individual molecules to a flow cell surface containing covalently attached oligonucleotides, sequentially adding fluorescently labeled nucleotides and a DNA polymerase, detecting incorporation events by laser excitation, and recording with a charge coupled device (CCD) camera. The fluorescent nucleotide prevents the incorporation of any subsequent nucleotide until the nucleotide dye moiety is cleaved. The images from each cycle are assembled to generate an overall set of sequence reads.

Another representative sequencing-by-synthesis platform involves constraining DNA to a zero-mode wave guide so small that light can penetrate only the region very close to the edge of the wave guide, where the polymerase used for sequencing is constrained. Only nucleotides in that small volume near the polymerase can be illuminated and their fluorescence can be detected. All four potential nucleotides are included in the reaction, each labeled with a different color fluorescent dye so that they can be distinguished from each other.

Yet another representative sequencing-by-synthesis platform is based on the fluorescence resonance energy transfer (FRET). This platform uses a quantum-dot-labeled polymerase that synthesizes DNA and four distinctly labeled nucleotides in a real-time system. Quantum dots, which are fluorescent semiconducting nanoparticles, have an advantage over fluorescent dyes in that they are much brighter and less susceptible to bleaching, although they are also much larger and more susceptible to blinking. The sample to be sequenced is ligated to a surface-attached oligonucleotide of defined sequence and then read by extension of a primer complementary to the surface oligonucleotide. When a fluorescently labeled nucleotide binds to the polymerase, it interacts with the quantum dot, causing an alteration in the fluorescence of both the nucleotide and the quantum dot. The quantum dot signal drops, whereas a signal from the dye-labeled phosphate on each nucleotide rises at a characteristic wavelength.

### Optical Sequencing and Mapping

Optical sequencing and mapping generally involves immobilizing a DNA molecule to be sequenced to a surface, cutting it with various restriction enzymes or labeling it after treatment with sequence-specific nicking enzymes.

### Nanopores

Sequencing by synthesis and optical sequencing and mapping platforms use some kind of label to detect the individual base for sequencing. In contrast, nanopore platforms generally do not require an exogenous label but rely instead on the electronic or chemical structure of the different nucleotides for discrimination. Representative nanopores include those based on solid-state materials such as carbon nanotubes or thin films and those based on biological materials such as α-hemolysin or MspA.

### BRIEF DESCRIPTION OF THE DRAWINGS

The above aspects and other aspects and features will become apparent to those ordinarily skilled in the art upon review of the following description of specific embodiments in conjunction with the accompanying figures, wherein:

FIG. 1A-FIG. 1E schematically shows the structure of a device suitable single molecule sequencing, according to an embodiment.

FIG. 1F schematically shows the high length to width ratio of the portion of the nanogap channel sandwiched between the directly facing portions of the electrodes of an electrode pair, according to an embodiment.

FIG. 1G shows scanning electron microscopy images of a partial cross-section along section B, according to an embodiment.

FIG. 2 schematically shows the structure of another device, according to an embodiment.

FIG. 3 schematically shows that the plurality of electrode pairs may be configured to identify products of incorporation reactions of nucleotides (e.g., dATP, dTTP, dGTP, and dCTP) into a complementary strand to a DNA molecule being sequenced, according to an embodiment.

FIG. 4 schematically shows redox cycling, according to an embodiment.

FIG. 5A-5D show various electric circuits that can be used to read and process signals from the electrode pairs, according to an embodiment.

FIG. 5E schematically shows circuits 300 in a unit cell 290 of the device 200 in FIG. 2 and the functions of the circuits, according to an embodiment.

FIG. 5F schematically shows alternative circuits 300, according to an embodiment.

FIGS. 6A-6J schematically show an exemplary fabrication method for the device, which allows using materials such as doped diamond or silicon carbide as the material of the electrode pair, according to an embodiment, according to an embodiment.

FIG. 7 shows electrochemical windows (as measured by cyclic voltammetry) of silicon carbide, glassy carbon, and boron-doped diamond, according to an embodiment.

FIG. 8A shows an electrode current as a function of the electrode potential with a model compound (ferrocene) of redox potential at about 0.24 V for electrodes made of platinum and doped diamond, according to an embodiment.

FIG. 8B shows cyclic voltammetry measurements with buffer solution, which indicate a larger operation window of the diamond electrode with much smaller background current than platinum electrode (diamond electrode registering close to no current while platinum electrode has an offset current due to background current), according to an embodiment.

FIG. 9A and FIG. 9B show an exemplary method of bonding a microfluidics chip, according to an embodiment.

FIG. 10A and FIG. 10B show a top view image of a microfluidic network and its overlay with the nanogap device, according to an embodiment.

### DETAILED DESCRIPTION

Embodiments will now be described in detail with reference to the drawings, which are provided as illustrative examples so as to enable those skilled in the art to practice the embodiments. Notably, the figures and examples below are not meant to limit the scope to a single embodiment, but other embodiments are possible by way of interchange of some or all of the described or illustrated elements. Wherever convenient, the same reference numbers will be used throughout the drawings to refer to same or like parts. Where certain elements of these embodiments can be partially or fully implemented using known components, only those portions of such known components that are necessary for an understanding of the embodiments will be described, and detailed descriptions of other portions of such known components will be omitted so as not to obscure the description of the embodiments. In the present specification, an embodiment showing a singular component should not be considered limiting; rather, the scope is intended to encompass other embodiments including a plurality of the same component, and vice-versa, unless explicitly stated otherwise herein. Moreover, applicants do not intend for any term in the specification or claims to be ascribed an uncommon or special meaning unless explicitly set forth as such. Further, the scope encompasses present and future known equivalents to the components referred to herein by way of illustration.

A sequencing technology would benefit from high throughput, single-molecule reading capability, pure electrical detection and capability with established fabrication processes. The benefits of pure electrical detection include the elimination of bulky and expensive optical detection systems and relatively unstable and expensive fluorescent labeling. The benefits of capability with established fabrication processes include easier integration with other microelectronic devices (e.g., for signal acquisition and processing) and lower production cost.

The term “tag” refers to a marker or indicator distinguishable by an observer. A tag may achieve its effect by undergoing a pre-designed detectable process. Tags are often used in biological assays to be conjugated with, or attached to, an otherwise difficult to detect substance. At the same time, tags usually do not change or affect the underlying assay process. A tag used in biological assays includes, but not limited to, a redox-active molecule.

The term “nucleotide” includes deoxynucleotides and analogs thereof. These analogs are those molecules having some structural features in common with a naturally occurring nucleotide such that when incorporated into a polynucleotide sequence, they allow hybridization with a complementary polynucleotide in solution. Typically, these analogs are derived from naturally occurring nucleotides by replacing and/or modifying the base, the ribose or the phosphodiester moiety. The changes can be tailor-made to stabilize or destabilize hybrid formation, or to enhance the specificity of hybridization with a complementary polynucleotide sequence as desired, or to enhance stability of the polynucleotide.

The term “sequence” refers to the particular ordering of monomers within a macromolecule and it may be referred to herein as the sequence of the macromolecule.

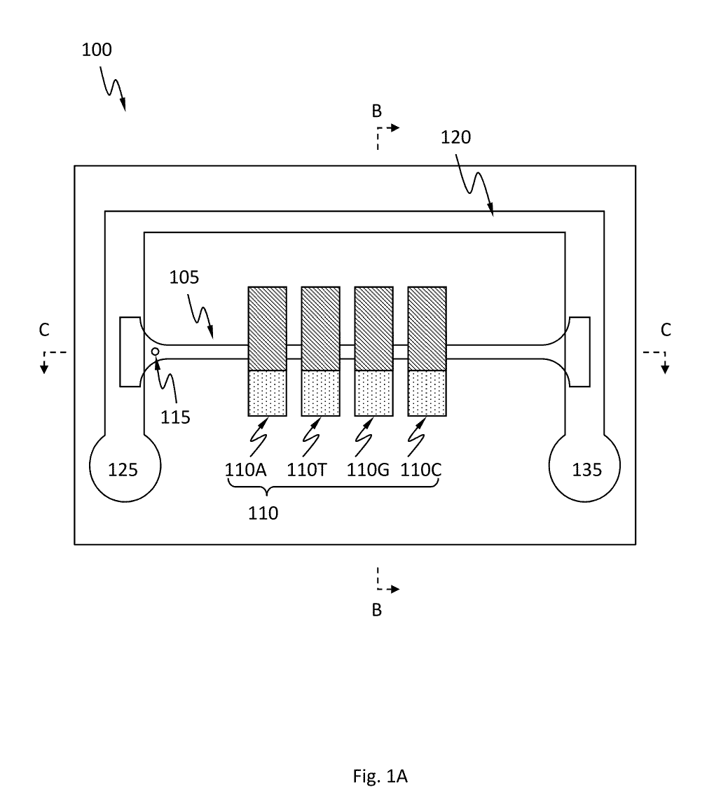

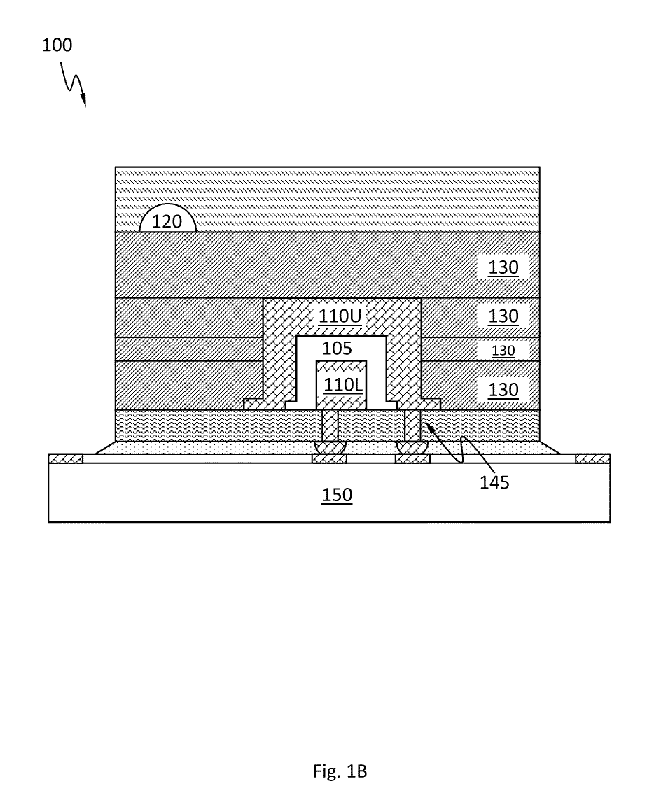

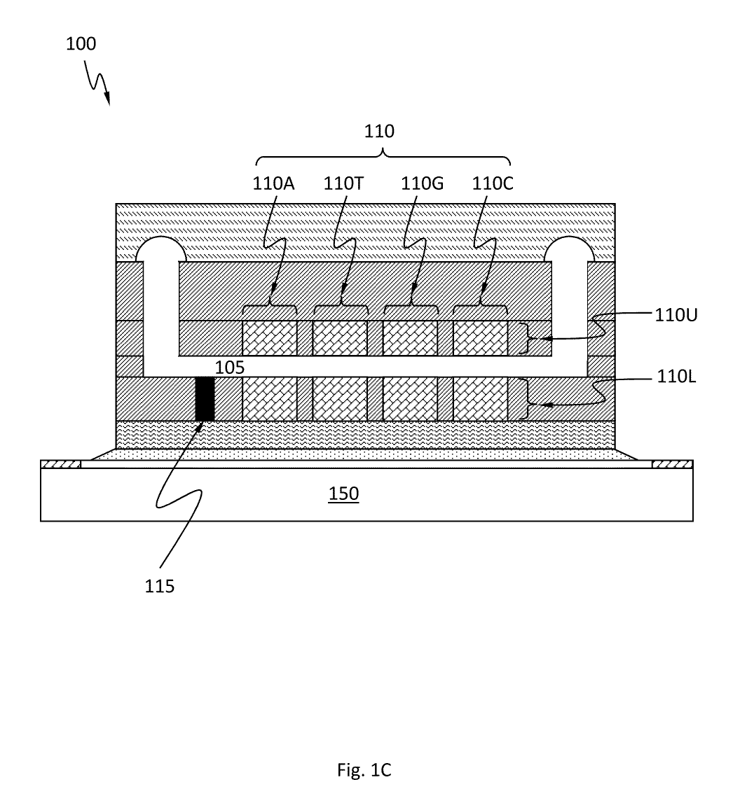

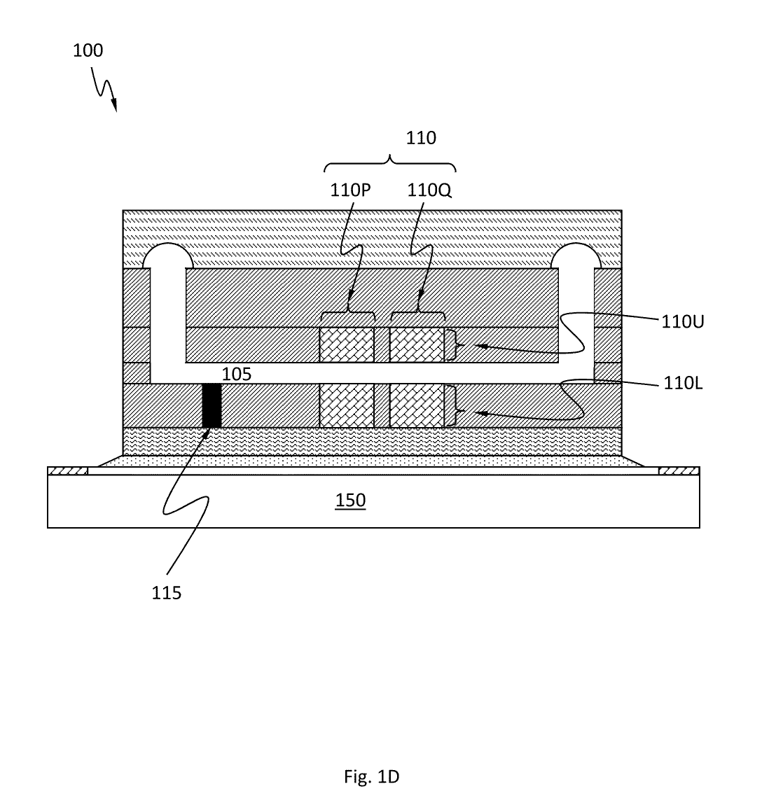

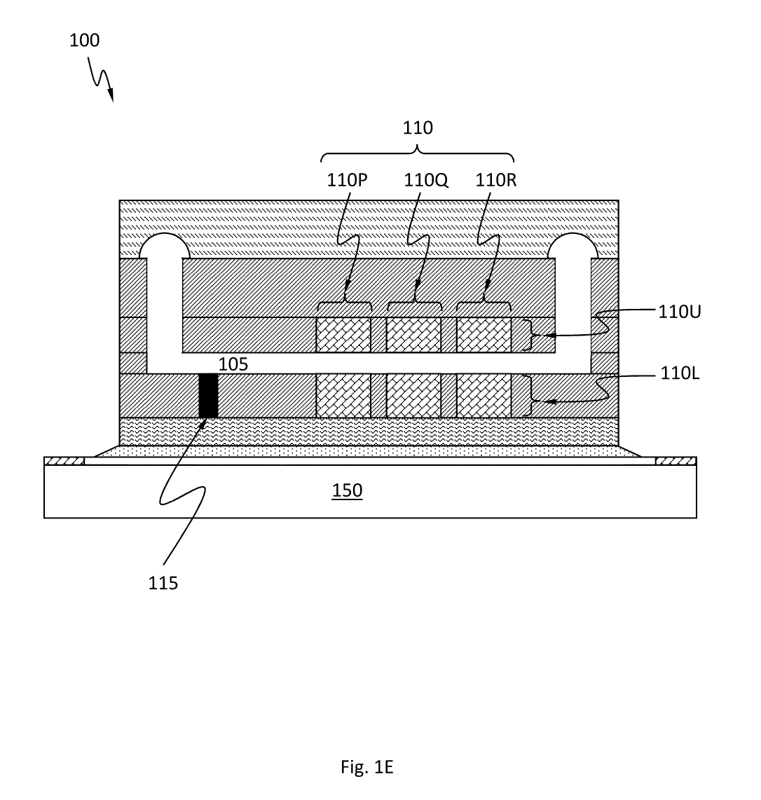

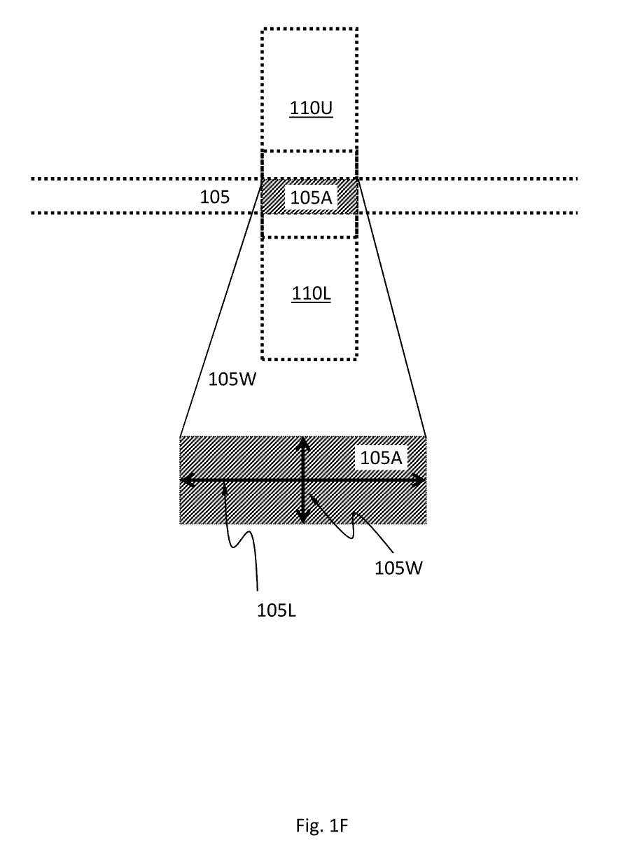

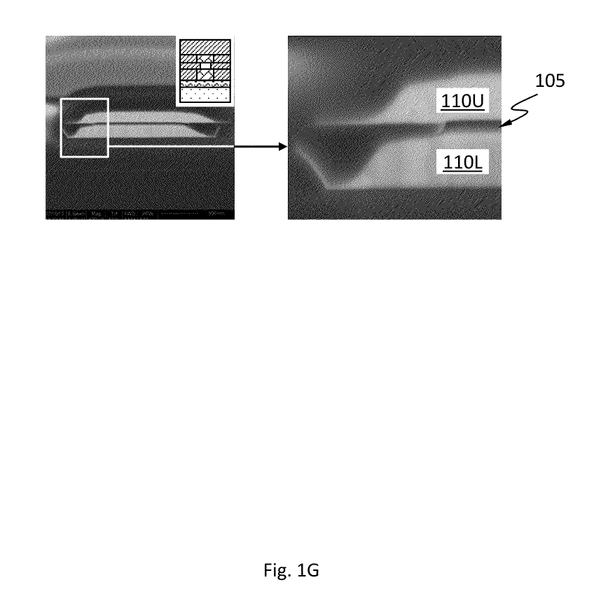

FIG. 1A-FIG. 1C schematically show the structure of a device suitable single molecule 100 sequencing, according to an embodiment. FIG. 1A shows a top view of this device 100. FIG. 1B shows a cross-sectional view along section B. FIG. 1C shows a cross-sectional view along section C. The device 100 has a nanogap channel 105 and a plurality of electrode pairs 110. The device 100 may further have any combination of a bioreactor 115, a bypass channel 120, an inlet 125, and an outlet 135. The plurality of electrode pairs 110 and the nanogap channel 105 may be formed in one or more layers 130 of dielectric materials. The plurality of electrode pairs 110 may be electrically connected to an electric circuit 150 through vias 145.

Each electrode pair among the plurality of electrode pairs 110 comprises a first electrode 110U and a second electrode 110L. The first electrode 110U may include one or more discrete pieces of conductors. The second electrode 110L may include one or more discrete pieces of conductors. A portion of the nanogap channel is sandwiched between the first electrode 110U and the second electrode 110L. At least a portion of the first electrode 110U directly faces at least a portion of the second electrode 110L, across the nanogap channel 105. The distance between these facing portions across the first dimension is 100 nm or less, 75 nm or less, 50 nm or less, 25 nm or less, 10 nm or less, 5 nm or less, or 1 nm or less. At least a portion of the first electrode 110U is exposed to an interior of the nanogap channel 105. At least a portion of the second electrode 110L is exposed to an interior of the nanogap channel 105. The phrase “exposed to an interior of the nanogap channel 105” means that the first electrode 110U, the second electrode 110L and the nanogap channel 105 are arranged such that a fluid filling the interior of the nanogap channel 105 directly contacts the first electrode 110U and the second electrode 110L. The first electrode 110U and the second electrode 110L are electrically conductive. The first electrode 110U and the second electrode 110L can be made of different materials or the same material. The first electrode 110U and the second electrode 110L preferably do not dissolve in water. The first electrode 110U and the second electrode 110L may include gold, platinum, palladium, silver, boron doped diamond and, alloys, mixtures or composites thereof. FIG. 1G shows scanning electron microscopy images of a partial cross-section along section B.

The nanogap channel 105 may fluidically and sequentially extend across each of the plurality of electrode pairs 110. The nanogap channel 105 and the plurality of electrode pairs 110 are arranged such that fluid flowing along the nanogap channel 105 passes between the first electrode 110U and the second electrode 110L of one of the electrode pairs 110 before the fluid passes between the first electrode 110U and the second electrode 110L of another of the electrode pairs 110. The nanogap channel 105 is not necessarily straight. A portion of the nanogap channel 105 between the first electrode 110U and the second electrode 110L of an electrode pair among the plurality of electrode pairs 110 may have a height (i.e., the distance separating the first electrode 110U and the second electrode 110L along the first dimension) of 100 nm or less, 75 nm or less, 50 nm or less, 25 nm or less, 10 nm or less, 5 nm or less, or 1 nm or less. The nanogap channel 105 may have a size across a second dimension (“width”) (i.e., the dimension perpendicular to the first dimension and the flow direction of the nanogap channel 105) of 500 nm or less, 250 nm or less, 100 nm or less, 50 nm or less, or 10 nm or less. The cross-sectional shape of the nanogap channel 105 perpendicular to the flow direction thereof may be rectangular, square, circular, elliptical or any other suitable shape.

As shown in FIG. 1F, the portion 105A of the nanogap channel 105 sandwiched between the directly facing portions of the electrodes 110U and 110L preferably has a high length 105L to width 105W ratio. The width can be a distance extending from one end of a cross-section of the nanogap channel 105 perpendicular to the flow direction to the other end (e.g., along the dotted line with two arrow heads). Preferably, the ratio is greater than 50:1, greater than 100:1, greater than 500:1, greater than 1000:1, or greater than 2000:1. Higher length 105L to width 105W ratio leads to more time a redox active molecule stays in the portion 105A and less stray capacitance due to the area of the fluid-electrodes interfaces.

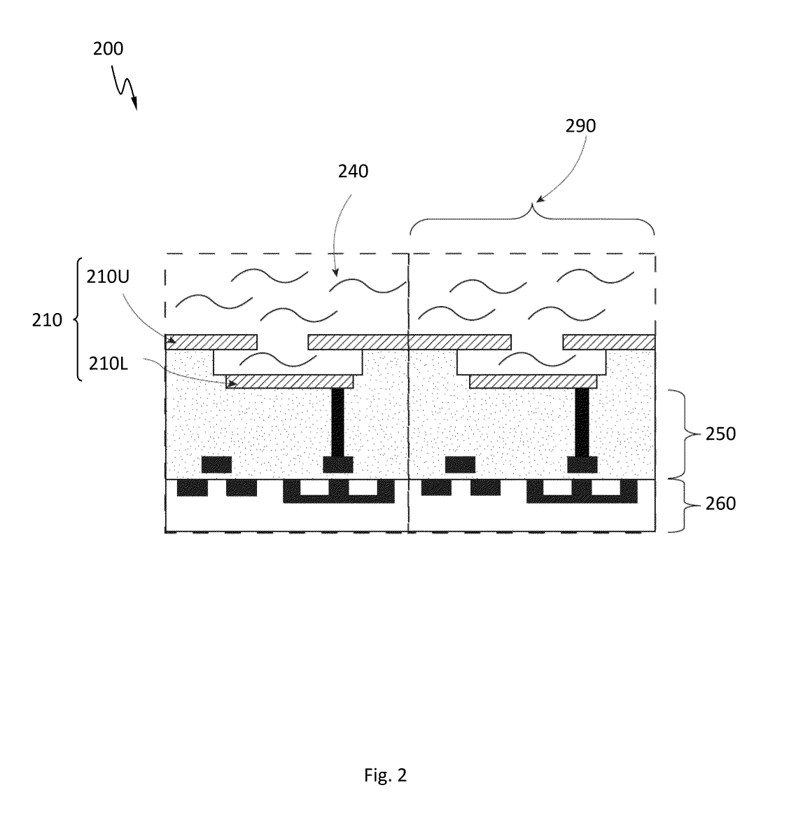

FIG. 2 schematically shows the structure of another device 200. The device 200 includes an array of unit cells 290. In at least one unit cell, the device has an electrode pair 210 with a first electrode 210U and a second electrode 210L, preferably both fabricated on a substrate and electrically isolated from each other. The electrodes 210U and 210L are configured to be exposed to a fluid 240. The device may further have transistors 260 in the unit cells (preferably 10 transistors or less in each unit cell, further preferable 3 transistors or less in each unit cell) and interconnect 250. The interconnect 250 electrically connects at least one (e.g., the first electrode 210U) of the electrodes 210U and 210L to the transistors 260. The transistors 260 may be configured to measure electrical current through at least one of (e.g., the first electrode 210U) of the electrodes 210U and 210L. A unit cell may comprise sensors such as the first electrode 210U, and circuitry dedicated to the sensors. The gap between electrodes 210U and 210L is preferably small, such as from 1 nm to 100 nm (a “nanogap”).

The plurality of electrode pairs 110 are configured to identify chemical species (e.g., four chemical species) passing therebetween and flowing in the nanogap channel 105, for example, by an electrical signal the chemical species generate on the plurality of electrode pairs 110. The electrical signal may be generated from an electrochemical reaction of the chemical species, from a chemical reaction of the chemical species, or a combination thereof. For example, the plurality of electrode pairs 110 may be electrically biased differently in order to identify the chemical species. A chemical species may undergo an electrochemical or chemical reaction at one or more electrical potentials (usually relative to a reference electrode or to the solution the chemical species is in) but not at others. If a first chemical species undergoes a reaction at a first potential and a second chemical species undergoes a reaction at a second potential different from the first potential, an electrode pair biased at the first potential will generate an electrical signal (e.g., voltage or current) when the first chemical species is present regardless whether the second chemical species is present, and an electrode pair biased at the second potential will generate an electrical signal (e.g., voltage or current) when the second chemical species is present regardless whether the first chemical species is present. A chemical species may undergo an electrochemical or chemical reaction with a material attached to an electrode pair but not with another material attached to another electrode pair. If a first chemical species undergoes a reaction with a first material and a second chemical species undergoes a reaction with a second material different from the first material, an electrode pair with the first material attached thereto will generate an electrical signal (e.g., voltage or current) when the first chemical species is present regardless whether the second chemical species is present, and an electrode pair with the second material attached thereto will generate an electrical signal (e.g., voltage or current) when the second chemical species is present regardless whether the first chemical species is present.

The device 100 of FIG. 1A-1C may be used to sequence peptides, DNAs and RNAs. DNA sequencing is used as an example to explain the operation of this device.

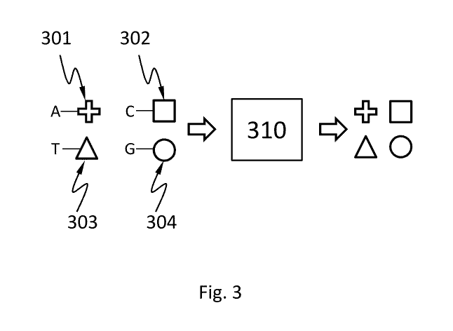

In the context of DNA sequencing, the plurality of electrode pairs 110 may be configured to identify products of incorporation reactions of nucleotides (e.g., dATP, dTTP, dGTP, and dCTP) into a complementary strand to a DNA molecule being sequenced, as schematically shown in FIG. 3. The reaction products may be a distinct tag 301, 302, 303 or 304 on each type (e.g., A, T, G, C) of the nucleotides introduced to react with the complementary strand, where upon incorporation 310 of the nucleotides, the distinct tag 301, 302, 303 or 304 is released from the nucleotides and can flow to the plurality of electrode pairs 110. The released tag may be “activated,” e.g., by using activating enzymes or other molecules, before flowing to the plurality of electrode pairs 110. Upon identifying the released tag by the plurality of electrode pairs 110, the type of the nucleotide incorporated is ascertained.

Alternatively, the plurality of electrode pairs 110 may be configured to identify products of digestion of a DNA molecule being sequenced. For example, the DNA molecule being sequenced may be digested by a nuclease to sequentially release the nucleosides or nucleotides in the DNA molecule. The released nucleosides or nucleotides flow to the plurality of electrode pairs 110 and are identified by them. Alternatively, the released nucleosides or nucleotides may be “activated,” e.g., by using activating enzymes or other molecules, to produce distinct tags that flow to the plurality of electrode pairs 110 and are identified by them. Upon identifying the released nucleosides or nucleotides or the tags by the plurality of electrode pairs 110, the type of the nucleotide incorporated is ascertained.

The plurality of electrode pairs 110 may have two, three, four, or more electrode pairs. The plurality of electrode pairs 110 are preferably independently addressable. In one embodiment, the plurality of electrode pairs 110 have four electrode pairs 110A, 110T, 110G and 110C. For example, electrode pairs 110A, 110T, 110G and 110C are configured (by biasing at four different potentials or by attaching with four different materials) such that they generate a signal when a tag released (or also activated) from incorporation of dATP, dTTP, dGTP or dCTP is present, respectively, or such that they generate a signal when an adenosine (or a deoxyadenosine), a thymidine (or a deoxythymidine), a guanosine (or a deoxyguanosine), a cytidine (or a deoxycytidine) released (or also activated) from digestion is present, respectively.

In one embodiment, as shown in FIG. 1D, the plurality of electrode pairs 110 have two electrode pairs 110P and 110Q. For example, electrode pairs 110P, and 110Q are configured (by biasing at two different potentials or by attaching with two different materials) such that electrode pair 110P generates a signal when a tag released (or also activated) from incorporation of a dTTP or dCTP is present; and such that electrode pair 110Q generates a signal when a tag released (or also activated) from incorporation of a dTTP or dATP is present.

In one embodiment, as shown in FIG. 1E, the plurality of electrode pairs 110 have three electrode pairs 110P, 110Q and 110R. For example, electrode pairs 110P, 110Q and 110R are configured (by biasing at three different potentials or by attaching with three different materials) such that electrode pair 110P generates a signal when a tag released (or also activated) from incorporation of a dTTP or dCTP is present; such that electrode pair 110Q generates a signal when a tag released (or also activated) from incorporation of a dTTP or dATP is present; and such that electrode 110R generates a signal when a tag released (or also activated) from incorporation of a dATP, dTTP, dGTP or dCTP is present.

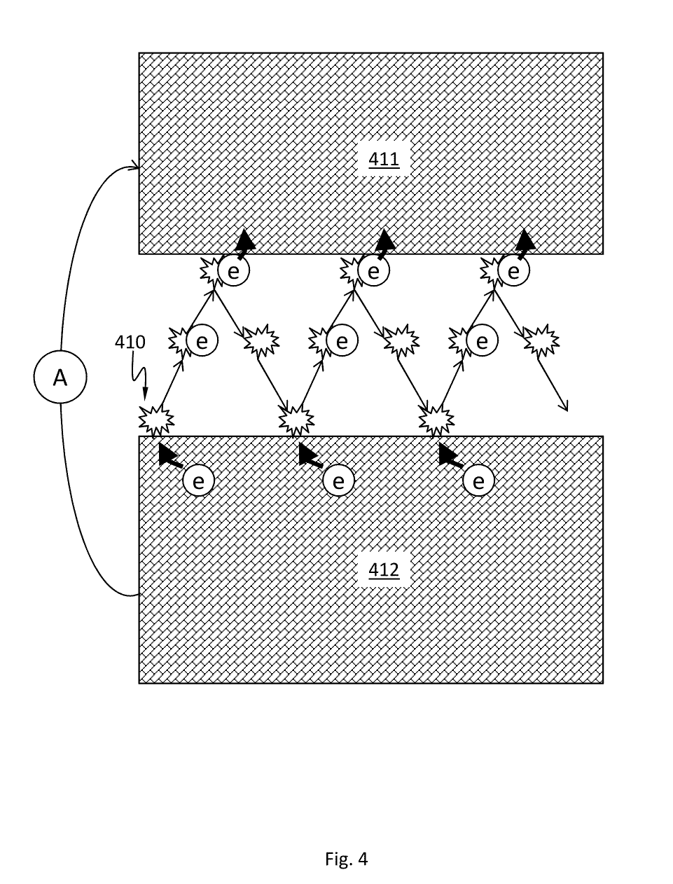

In an embodiment, identification of a chemical species by an electrode pair involves redox cycling. Redox cycling can be especially useful when only a few or even a single molecule of the chemical species are available for identification. FIG. 4 schematically shows redox cycling. Redox cycling is an electrochemical method in which a molecule 410 that can be reversibly oxidized and/or reduced (i.e., a redox active molecule) moves between at least two electrodes 411 and 412, one of which biased below a reduction potential and the other of which biased above an oxidation potential for the molecule being detected, shuttling electrons between the electrodes (i.e., the molecule is oxidized at a first electrode 411 and then diffuses to a second electrode 412 where it is reduced or vice versa, it is first reduced and then oxidized, depending on the molecule and the potentials at which the electrodes are biased). The same molecule 410 can therefore contribute a plurality of electrons to the recorded current resulting in the net amplification of the signal (e.g., presence of molecule 410). In a redox cycling measurement, the electrodes 411 and 412 are used to repeatedly flip the charge state of a redox active molecule 410 in solution allowing a single redox active molecule to participate in multiple redox reactions and thereby contribute multiple electrons to an electric current between the electrodes 411 and 412. In redox cycling measurements, the height of the gap between the electrodes 411 and 412 can be on the nanometer scale. In the device of FIG. 1A-FIG. 1C, the height of the gap is the height of the nanogap channel 105. A single redox active molecule 410 flowing between the two electrodes 411 and 412 can shuttle multiple electrons (e.g., >100) between the electrodes 411 and 412, leading to amplification of the measured electrochemical current. The number of electrons a single redox active molecule 410 can shuttle depends on factors such as the stability of the redox active molecule 410 and the time the redox active molecule 410 spends in the region between the electrodes 411 and 412. The magnitude of current through either electrode is proportional to the concentration of the redox active molecule 410 in the region between the electrodes 411 and 412 and to the number of electrons the redox active molecule 410 shuttles from one electrode to the other. In the device of FIG. 1A-FIG. 1C, the number of electrons shuttled from one electrode to the other electrode of an electrode pair by one redox active molecule 410 may depend on the length of the portion of the nanogap channel 105 sandwiched by the electrode pair. A redox active molecule is a molecule that is capable of reversibly cycling through states of oxidation and/or reduction a plurality of times.

According to an embodiment, the bioreactor 115 may be arranged such that all reaction products from the bioreactor 115 flow into the nanogap channel 105 and by the plurality of electrode pairs 110. The bioreactor 115 may be positioned inside the nanogap channel 105 and upstream to the plurality of electrode pairs 110. The bioreactor 115 is not necessarily inside the nanogap channel 105. The bioreactor 115 may be an area with a functionalized surface. The bioreactor 115 may be an area of different materials from its surrounding areas. For example, the bioreactor 115 may be an area of silicon oxide or gold. Being an area made of a different material makes surface functionalization easier. For example, if the bioreactor 115 is the only component made of gold that is exposed to the interior of the nanogap channel 105, the surface of the bioreactor 115 can be modified by flowing a ligand that only reacts with gold through the nanogap channel 105. The functionalized surface may be used as a site to immobilize a molecule thereon. The molecule may be a polymerase, a nuclease, a DNA or RNA strand, or a peptide. The bioreactor 115 preferably has a small area (e.g., 100 nm or less in diameter) so that statistically only one molecule is immobilized thereon.

A flow through the nanogap channel 105 may be induced. The flow preferably transports reaction products from the bioreactor 115 through the nanogap channel 105 sequentially, in an order of time of release (e.g., dissociation from any immobilized molecule into the flow) of the reaction products. Namely, the flow transports a reaction product released earlier before a reaction product released later. The flow preferably is at a rate that preserves the order of the reaction products before they pass the last electrode pair. The flow rate may be as low as in the range of pl/min (picoliters per minute). The flow may be induced by a pressure differential between the inlet 125 and the outlet 135. When the pressure differential dictated by the desired flow rate is too small to be practically maintained, the device 100 can have a bypass channel 120 fluidically parallel with the nanogap channel 105. For example, if the practically maintainable flow rate is in the range of μl/min. The bypass channel 120 can be much wider than the nanogap channel 105 so that the fraction through the latter is at a much smaller flow rate. The bypass channel 120 may have a valve that can controllably shut it off.

The electric circuit 150 may be a chip of CMOS electronics. The rest of the device 100 may be attached to the electric circuit 150 by a suitable technique such as solder microbumps.

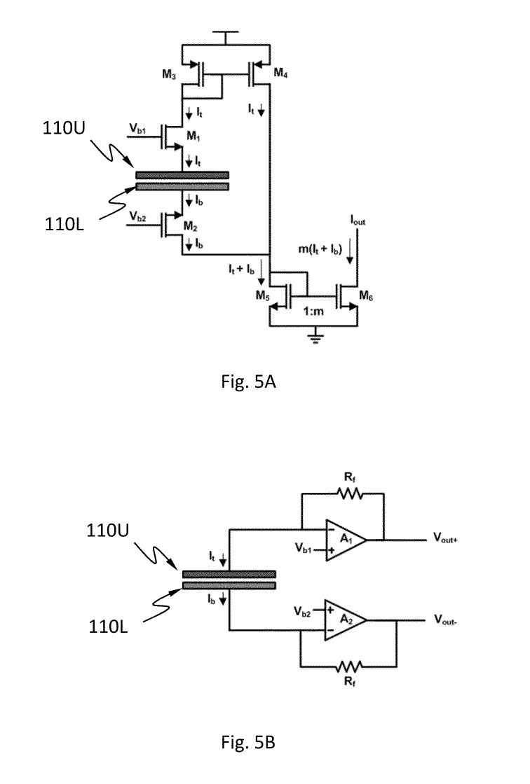

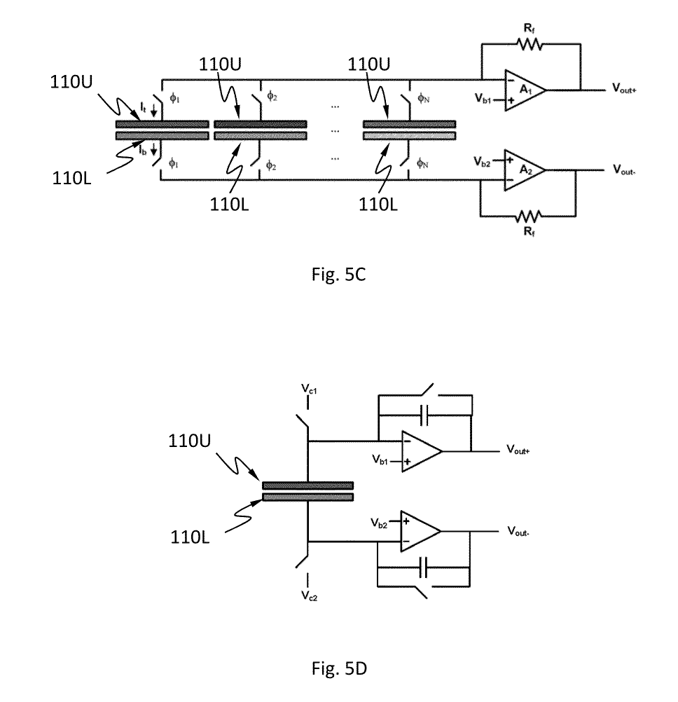

The electric circuit 150 may have the sensitivity and foot print size to match the density of the electrode pairs. Multiple electrode pairs may share the same circuit. The electric circuit 150 may be configured to read or process signals on the electrode pairs. In an embodiment, the electric circuit 150 is configured to read a differential of the potential on the first electrode 110U and the second electrode 110L of an electrode pair (e.g., FIG. 5A). In an embodiment, the electric circuit 150 is configured to use transimpedance amplifiers to amplify the signal by cross-correlation signal processing techniques to reduce the amplifier noise (e.g., FIG. 5B). In an embodiment, the electric circuit 150 is configured to allow sharing of the circuit among multiple electrode pairs (e.g., FIG. 5C) in a time domain multiplexed fashion.

FIG. 5A is an example of the electric circuit 150 that uses two common gate amplifiers (M1 and M2) which set the electrode potentials approximately Vb1-Vt and Vb2-Vt (Vt is the threshold voltage) while relaying the electrode current to either a current mirror formed by M3/M4 (which inverts it) or to the summing node directly. The current mirror formed by M5 and M6 provides amplification and an interface to a current-mode ADC or other means of acquiring the resulting current, which can be shared between many electrode pairs.

FIG. 5B is an example of the electric circuit 150 that independently acquires signals from both electrodes so that cross-correlation signal processing techniques can be used to reduce the impact of the amplifier (A1 and A2) noises.

FIG. 5C is an extension of the readout circuit in FIG. 5B, where the amplifiers are shared among many electrode pairs. Switches controlled by non-overlapping control signals may be used to address each of the electrode pairs.

FIG. 5D is a switched capacitor implementation of a pair of transimpedance amplifiers with two separate outputs, which can be used for cross-correlation or similar signal processing. Furthermore, the other switches (e.g., V01,V02) can implement controllable current cancellation (switches can either be connected to a voltage source or to a capacitor). By means of logic controlling the switches, it is possible to implement hardware subtraction or detection of anti-correlated currents at the electrodes. As shown in FIG. 5D, a switched capacitor approach can be used to implement the transimpedance amplifier as well as perform background subtraction of the current traces (to ideally remove any portion not attributable to the redox active molecules) as well as implementing some level of cross-correlation in the circuitry.

Preferably, a redox active molecule that is oxidized or reduced at one of the electrodes 110U and 110L diffuses to the other electrode to complete the redox cycling. However, if the redox active molecule diffuses to some place other than the other electrode, the redox cycling is broken, which causes noise in the signal. Preferably, the electrode pairs are configured such that the redox active molecule can only diffuse back and forth between the electrodes 110U and 110L while it is in the portion of the nanogap channel 105 sandwiched therebetween. If the width of the nanogap channel 105 is not larger than the width of the directly facing portions of the electrodes and is entirely sandwiched between the directly facing portions, the redox cycling is not broken because the redox active molecule can only diffuse back and forth between the electrodes 110U and 110L.

FIG. 5E schematically shows circuits 300 in a unit cell 290 of the device 200 in FIG. 2 and the functions of the circuits. According to an embodiment, electrical current through an electrode may be measured by measuring the rate of charging or discharging of capacitance of that electrode. For example, electrical current through the first electrode 210U may be measured by measuring the rate of charging or discharging of capacitance 233 of the first electrode 210U. Although the capacitance 233 of the first electrode 210U is depicted in FIG. 5E as a capacitor separate from the capacitance, it need not comprise a physical capacitor component, but a combination of self-capacitance of the first electrode 210U and capacitance of the interface between the first electrode 210U and the fluid 240. The fluid 240 may be a solution, e.g., aqueous solution or non-aqueous solution. The fluid 240 may be a gaseous phase. The fluid 240 may also be a molten electrolyte such as molten salt.

The circuitry connected to the first electrode 210U as depicted in FIG. 5E is one example that can be used to measuring the rate of charging or discharging of the capacitance 233. In an embodiment, switch 232 is closed to connect the first electrode 210U to a bias source 231. At this state, the voltage on the first electrode 210U is at the voltage of the bias source 231, denoted as V0. The switch 232 may be any circuitry that can electrically connect and disconnect the first electrode 210U to the bias source 231. For example, the switch 232 may be a toggle switch, a relay or a transistor. After the switch 232 is opened to disconnect the first electrode 210U from the bias source 231, redox reactions (electron transfer between the electrode and a chemical species in the solution) occurring at the first electrode 210U start to charge or discharge the capacitance 233 and as a result the voltage of the first electrode 210U deviates from V0. The rate of charging and discharging of the capacitance 223 can be derived from the change of the voltage of the first electrode 210U. The voltage of the first electrode 210U may be measured using any suitable circuitry 234. Circuitry 234 is not limited to a voltmeter. In an embodiment, the circuitry 234 may comprise A/D converter. In an embodiment, the circuitry 234 may comprise a buffer. The buffer may drive an A/D converter shared with other electrodes.

The circuitry connected to the first electrode 210U as depicted in FIG. 5F is another example that can be used to measuring the rate of charging or discharging of the capacitance 233. In an embodiment, switch 332 is closed to connect a charging electrode 333 disposed in the fluid 240 to a bias source 331. The voltage on the charging electrode 333 may affect the potential of the fluid 240 which affects the voltage on the first electrode 210U. At this state, the voltage on the first electrode 210U is at a voltage, denoted as V0. The switch 332 may be any circuitry that can electrically connect and disconnect the charging electrode 333 to the bias source 331. In one embodiment, the bias source 331 may output more than one voltages. For example, the switch 332 may be a toggle switch, a relay or a transistor. After the switch 332 is opened to disconnect the charging electrode 333 from the bias source 331, redox reactions (electron transfer between the electrode and a chemical species in the solution) occurring at the first electrode 210U start to charge or discharge the capacitance 233 and as a result the voltage of the first electrode 210U deviates from V0. The rate of charging and discharging of the capacitance 223 can be derived from the change of the voltage of the first electrode 210U. The voltage of the first electrode 210U may be measured using any suitable circuitry 234. Circuitry 234 is not limited to a voltmeter. In an embodiment, the circuitry 234 may comprise A/D converter. In an embodiment, the circuitry 234 may comprise a buffer. The buffer may drive an A/D converter shared with other electrodes. Although the charging electrode 333 is depicted as a separate electrode from electrodes 210U and 210L, the charging electrode 333 may be one or both of electrodes 210U and 210L.

The device 100 may face several challenges. One challenge is noise. Noise is especially detrimental when the number of the redox active molecules between the electrode pair 110 is low, such as in the application of single molecule sequencing. One source noise is the background noise such as leakage current between the electrode pair 110 through the fluid in the nanogap channel 105 or through insulator between the electrode pair 110. Another challenge is the absorption of the redox active molecule on the surface of the nanogap channel 105 or on the electrode pair 110. Once the redox active molecule is absorbed, it ceases to contribute to the electrical signal. If there is only one redox active molecule between the electrode pair 110 at a time, its absorption may prevent the identification of that one redox active molecule. If an absorbed redox active molecule is desorbed later, it may lead to a sequencing error. Yet another challenge is that the bias on the electrode pair 110 is limited. If the electrical bias on an electrode exposed to the fluid in the nanogap channel 105 is too high, the material of the electrode may start to undergo an electrochemical reaction, which may lead to failure of the device and a very high background current. The limited range of bias may limit the selection of the redox active molecule.

Several materials as the material of the electrode pair 110 help to overcome these challenges. Doped diamond (e.g., boron doped or nitrogen doped) and silicon carbide standout among these materials. Doping concentrations for boron doped diamond may be in the range of 10²⁰ atoms/cm³ to 10²² atoms/cm³. The doped diamond can be microcrystalline or nanocrystalline. However, deploying doped diamond or silicon carbide has its unique challenges. One important challenge is that depositing doped diamond or silicon carbide of sufficient high quality (e.g., smooth film, no pinholes, etc.) usually requires high temperature or exposure to a harsh environment (e.g., plasma). The high temperature or the exposure to harsh environment may prevent depositing these materials onto a functioning electric circuit 150 (e.g., a CMOS chip).

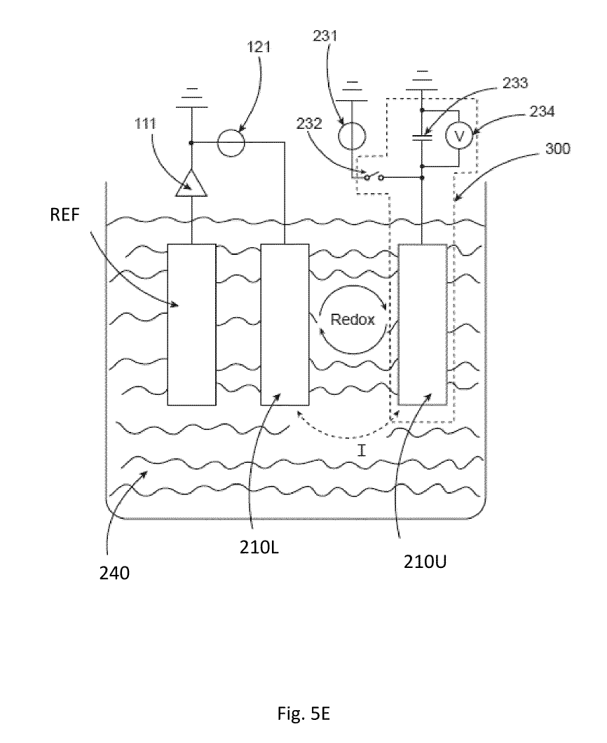

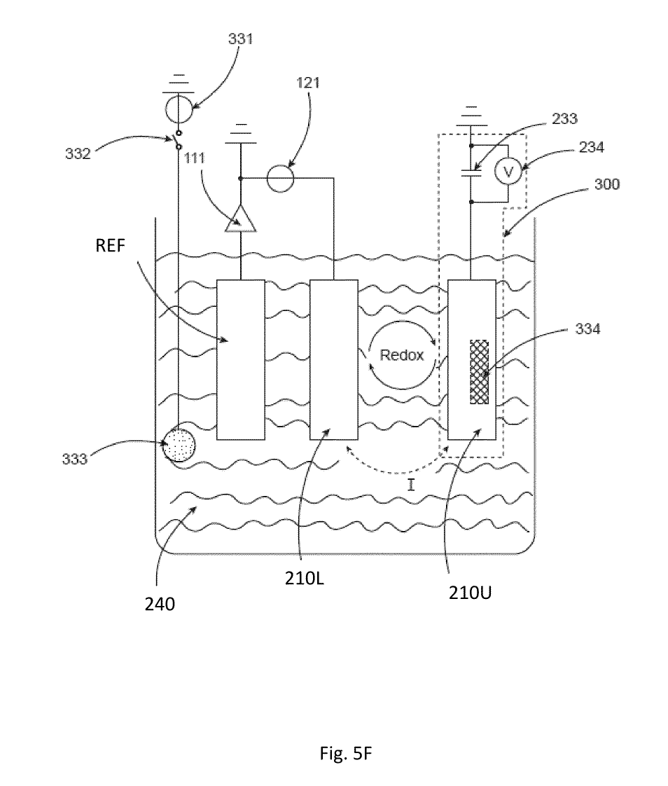

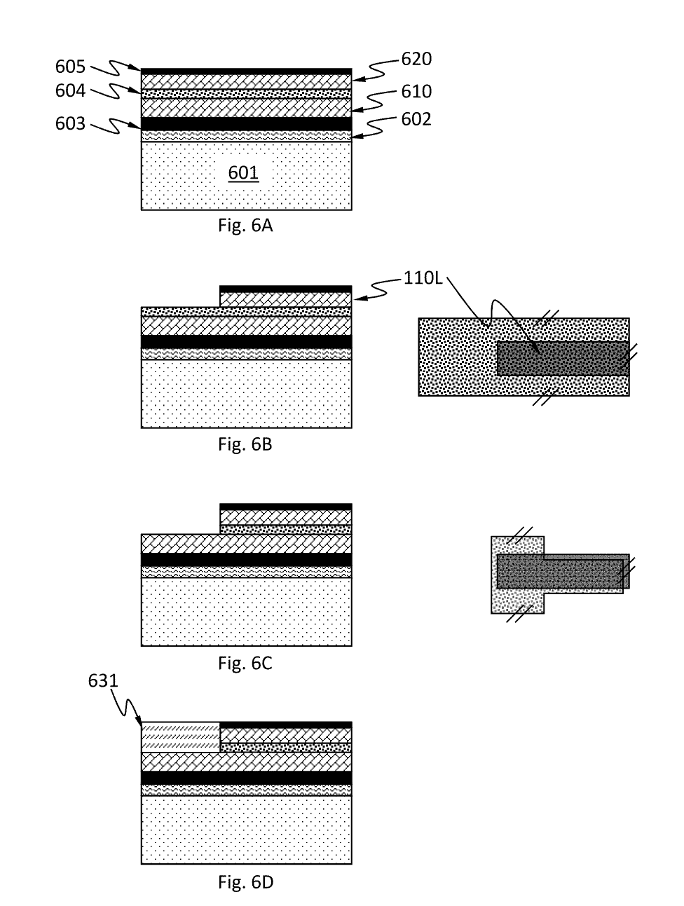

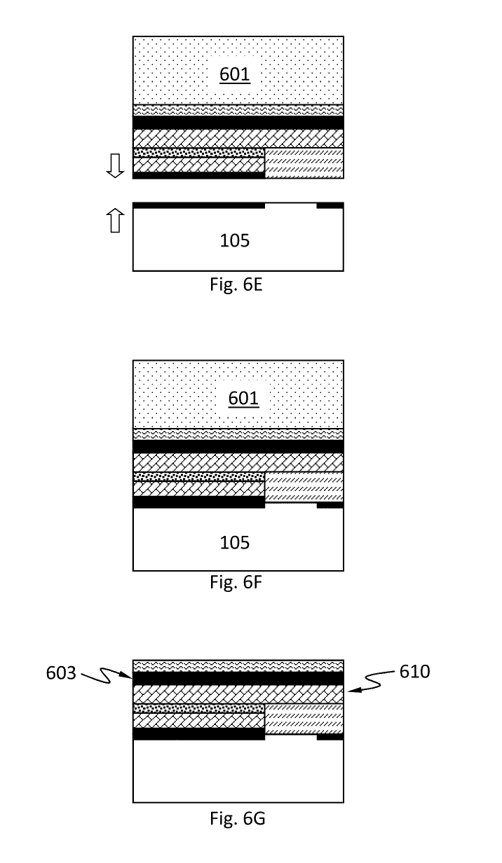

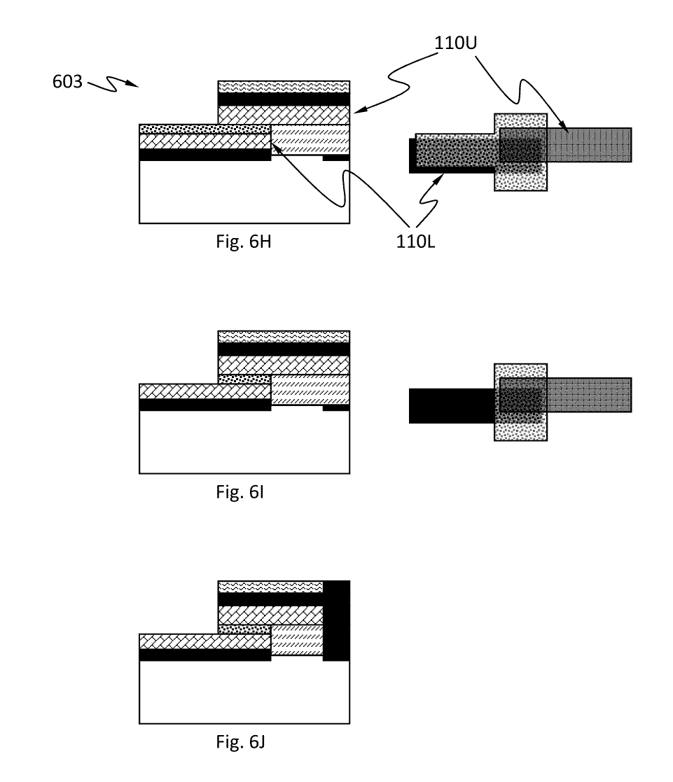

FIGS. 6A-6J schematically show an exemplary fabrication method for the device 100, which allows using materials such as doped diamond or silicon carbide as the material of the electrode pair 110, according to an embodiment.

As shown in FIG. 6A, a first material layer 610 (e.g., doped diamond or silicon carbide) may be deposited onto a carrier substrate 601. The substrate 601 can be any suitable material such as silicon. The substrate 601 may have an insulator layer 602 and/or a first conductor layer 603 (e.g., copper) before the deposition of the first material layer 610. The first conductor material 603 may form an Ohmic contact to the first material layer 610. The first material layer 610 may be deposited using any suitable method such as microwave plasma chemical vapor deposition (CVD) at a high temperature such as 700° C., laser-assisted CVD, low-pressure CVD at a high temperature such as 700° C. to 900° C., hot filament CVD at a high temperature such as 700° C. to 900° C., or another plasma-enhanced CVD technique.

A sacrificial layer 604 may be deposited on the first material layer 610. The sacrificial layer 604 will later be patterned using suitable techniques such as photolithography, and removed to form the nanogap channel 105. Chromium (Cr), tantalum nitride (TaN) and tungsten (W) are examples of the material of the sacrificial layer 604 due to their capability of being selectively etched compared to the other materials in the device 100. The sacrificial layer 604 may be deposited using any suitable technique (e.g., thermal deposition, e-beam deposition, sputtering, CVD, etc.).

A second material layer 620 (e.g., doped diamond or silicon carbide) may be deposited onto the sacrificial layer 604. The material of the second material 620 is not necessarily the same as the material of the first material layer 610. The second material layer 620 may be deposited using any suitable method such as microwave plasma chemical vapor deposition (CVD) at a high temperature such as 700° C., laser-assisted CVD, low-pressure CVD at a high temperature such as 700° C. to 900° C., hot filament CVD at a high temperature such as 700° C. to 900° C., or another plasma-enhanced CVD technique.

A second conductor layer 605 (e.g., copper) may be deposited onto the second material layer 620. The second conductor layer 605 may form an Ohmic contact to the second material layer 620.

As shown in FIG. 6B, the second material layer 620 and the second conductor 605 are patterned using a suitable technique such as photolithography to form the second electrode 110L. The right panel of FIG. 6B shows a schematic top view of the second electrode 110L (intentionally shown as semitransparent to allow viewing of the sacrificial layer 604 below) on the sacrificial layer 604.

As shown in FIG. 6C, the sacrificial layer 604 is patterned using a suitable technique such as photolithography. The portion that occupies the space of the nanogap channel 105 and the portion under the second electrode 110L are retained. The right panel of FIG. 6C shows a schematic top view of the second electrode 110L (intentionally shown as semitransparent and offset to allow viewing of the remainder of the sacrificial layer 604 below) and the remainder of the sacrificial 604.

As shown in FIG. 6D, void space left by the removed portion of the second material layer 620, the second conductor layer 605 and the sacrificial layer 604 is filled with an insulator 631 and is planarized if needed.

As shown in FIG. 6E, the carrier substrate 601 is reversed and the second electrode 110L is bonded to exposed contact pad (e.g., copper) of the electric circuit 105 through the second conductor layer 605 using a suitable technique. One method of bonding involves pressing the carrier substrate 601 onto the electric circuit 105 and applying heat to about 400° C. The second conductor layer 605 and the contact pad may be bonded by a diffusional creep process. Another possible bonding technique is dielectric bonding at about 400° C.

FIG. 6F shows the result of bonding.

As shown in FIGS. 6F-6G, the carrier substrate 601 is removed, e.g., by grinding or etching.

As shown in FIG. 6H, the first conductor layer 603, the first material layer 610, and the insulator layer 602 (if present) are patterned using a suitable technique such as photolithography to form the first electrode 110U. The right panel of FIG. 6H shows a schematic top view of the first electrode 110U (intentionally shown as semitransparent and offset to allow viewing of the remainder of the sacrificial layer 604), the remainder of the sacrificial 604 (intentionally shown as semitransparent and offset to allow viewing of the second electrode 110L below), and the second electrode 110L.

As shown in FIG. 6I, the remainder of the sacrificial layer 604 is patterned using a suitable technique such as photolithography. The portion that occupies the space of the nanogap channel 105 are retained. The portion that was under the second electrode 110L before bonding to the electrical circuit 105 and now exposed is removed. The right panel of FIG. 6I shows a schematic top view of the first electrode 110U (intentionally shown as semitransparent and offset to allow viewing of the remainder of the sacrificial layer 604), the remainder of the sacrificial 604 (intentionally shown as semitransparent and offset to allow viewing of the second electrode 110L below), and the second electrode 110L.

As shown in FIG. 6J, the first electrode 110U is electrically connected to the electric circuit 105.

The remainder of the sacrificial layer 604 may be etched away after being exposed to fluidic channels.

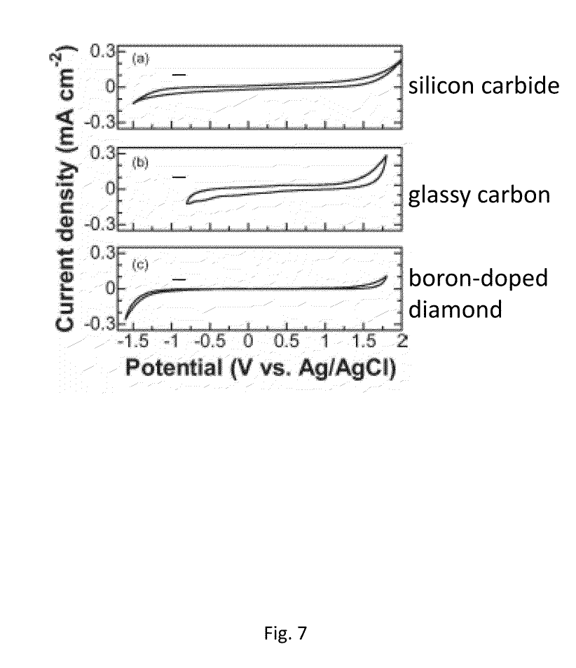

FIG. 7 shows electrochemical windows (as measured by cyclic voltammetry) of silicon carbide, glassy carbon, and boron-doped diamond. Boron-doped diamond has the largest electrochemical window of 3.2 V and silicon carbide has the second largest electrochemical window of 3V, both much larger than the electrochemical window of glassy carbon.

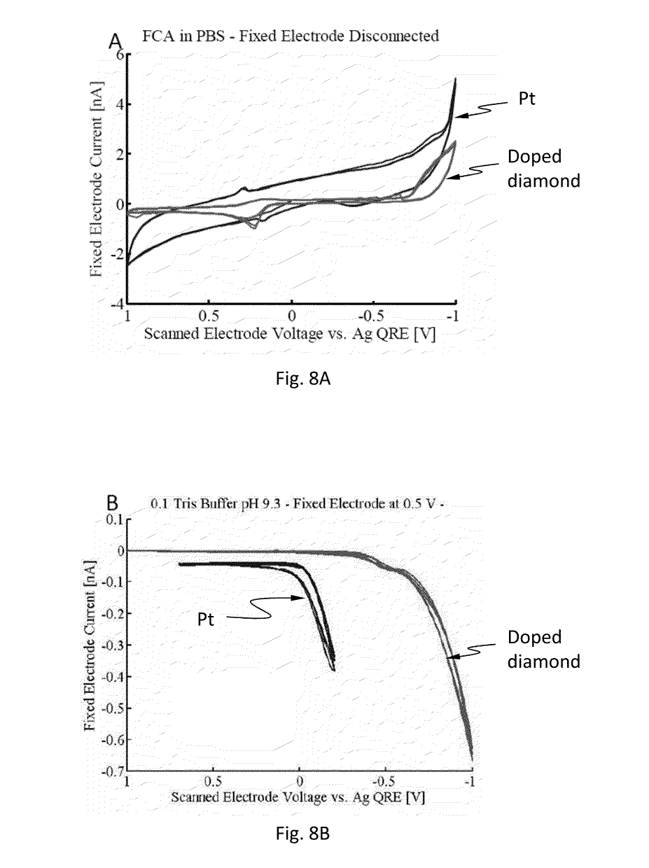

FIG. 8A shows an electrode current as a function of the electrode potential with a model compound (ferrocene) of redox potential at about 0.24 V for electrodes made of platinum and doped diamond. The background current is much smaller on the electrode made of doped diamond than on the electrode made of platinum.

FIG. 8B shows cyclic voltammetry measurements with buffer solution, which indicate a larger operation window of the diamond electrode with much smaller background current than platinum electrode (diamond electrode registering close to no current while platinum electrode has an offset current due to background current).

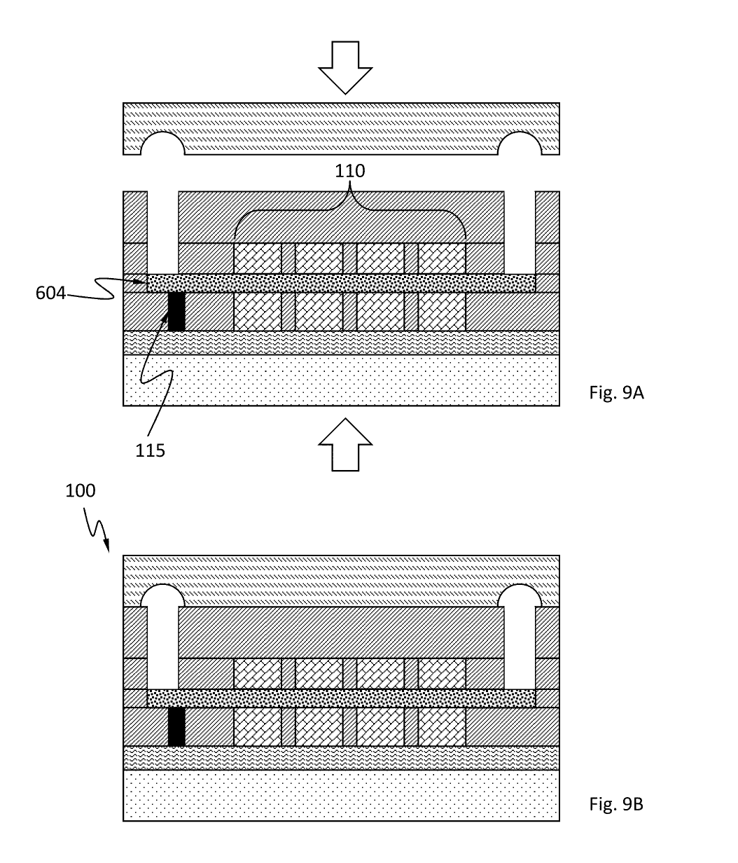

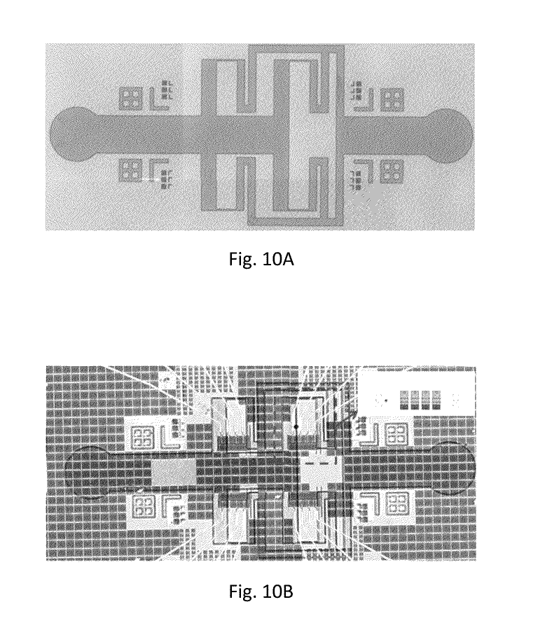

FIG. 9A and FIG. 9B show an exemplary method of bonding a microfluidics chip (e.g., on a borosilicate wafer) including the device bypass channel 120 with the dielectric layer 130. The microfluidics chip may be anodically bonded. The microfluidics chip may be made by etching patterns into a borosilicate wafer. Borosilicate may be composed of about 80% silica, about 13% boric oxide, about 3% aluminum oxide, and about 4% sodium oxide. Microfluidic channels can have a depth of 2-3 μm. Ports such as inlet 125 and outlet 135 and, if necessary, electrical connections maybe ultrasonically drilled into the borosilicate wafer. Anodical bonding supports a high-pressure (<300 psi) driven fluidic system. A high voltage (>1000 V) and bonding time (>30 minutes) may be utilized. The borosilicate wafer not only can carry a microfluidic network, but also can function as a handling wafer for subsequent bonding with the electric circuit 150. FIG. 10A and FIG. 10B show a top view image of a microfluidic network and its overlay with the nanogap device.

### EXAMPLES

Disclosed herein is a device comprising: an electrode pair comprising a first electrode and a second electrode; a nanogap channel; wherein a portion of the nanogap channel is sandwiched between the first electrode and the second electrode; wherein at least a portion of the first electrode directly faces at least a portion of the second electrode, across the nanogap channel; wherein the portion of the first electrode and the portion of the second electrode are exposed to an interior of the nanogap channel; and wherein the first electrode or the second electrode comprises doped diamond, silicon carbide or a combination thereof.

According to an embodiment, the first electrode and the second electrode are not electrically shorted.

According to an embodiment, the nanogap channel has a height of 100 nm or less, 75 nm or less, 50 nm or less, 25 nm or less, 10 nm or less, 5 nm or less, or 1 nm or less.

According to an embodiment, the device a plurality of electrode pairs and the nanogap channel fluidically and sequentially extends across each of the plurality of electrode pairs.

According to an embodiment, the nanogap channel has a width of 500 nm or less, 250 nm or less, 100 nm or less, 50 nm or less, or 10 nm or less.

According to an embodiment, the nanogap channel has a cross-sectional shape of rectangular, device, circular, elliptical shape.

According to an embodiment, the first and second electrodes are configured to be electrically biased.

According to an embodiment, the device has only two electrode pairs.

According to an embodiment, the device has only three electrode pairs.

According to an embodiment, the electrode pair is configured to identify a product of incorporation reactions of nucleotides into a complementary strand to a DNA molecule being sequenced.

According to an embodiment, the electrode pair is configured to identify a product of digestion of a DNA molecule being sequenced.

According to an embodiment, the device further comprises a bioreactor.

According to an embodiment, the bioreactor is arranged such that all reaction products from the bioreactor flow into the nanogap channel and the electrode pair.

According to an embodiment, the bioreactor is inside the nanogap channel.

According to an embodiment, the bioreactor is an area with a functionalized surface.

According to an embodiment, a molecule is immobilized to the bioreactor, wherein the molecule is selected from a group consisting of a polymerase, a nuclease, a DNA or RNA strand, and a peptide.

According to an embodiment, the device further comprises a bypass channel fluidically parallel with the nanogap channel.

According to an embodiment, a portion of the nanogap channel sandwiched between the portion of the first electrode and the portion of the second electrode has a length to width ratio of greater than 50:1, greater than 100:1, greater than 500:1, greater than 1000:1, or greater than 2000:1.

Disclosed herein is a method comprising: forming on a carrier substrate a first material layer comprising doped diamond, silicon carbide or a combination thereof; bonding the first material layer onto an electrical circuit.

According to an embodiment, the method further comprises forming a sacrificial layer on the first material layer.

According to an embodiment, the sacrificial layer is selected from a group consisting of Cr, TaN, W and a combination.

According to an embodiment, the sacrificial layer has a thickness of 100 nm or less, 75 nm or less, 50 nm or less, 25 nm or less, 10 nm or less, 5 nm or less, or 1 nm or less.

According to an embodiment, the method further comprises forming on the sacrificial layer a second material layer comprising doped diamond, silicon carbide or a combination thereof.

According to an embodiment, the method further comprises patterning the second material layer to form a second electrode.

According to an embodiment, the method further comprises patterning the sacrificial layer.

According to an embodiment, the method further comprises patterning the first material layer to form a first electrode.

According to an embodiment, the method further comprises removing the sacrificial layer to form a nanogap channel.

According to an embodiment, a portion of the nanogap channel is sandwiched between the first electrode and the second electrode.

According to an embodiment, at least a portion of the first electrode directly faces at least a portion of the second electrode, across the nanogap channel.

According to an embodiment, the portion of the first electrode and the portion of the second electrode are exposed to an interior of the nanogap channel.

According to an embodiment, a portion of the nanogap channel sandwiched between a portion of the first electrode and a portion of the second electrode has a length to width ratio of greater than 50:1, greater than 100:1, greater than 500:1, greater than 1000:1, or greater than 2000:1.

The descriptions above are intended to be illustrative, not limiting. Thus, it will be apparent to one skilled in the art that modifications may be made to the embodiments as described without departing from the scope of the claims set out below.

What is claimed is:

1. A device comprising:
an electrode pair comprising a first electrode and a second electrode;
a nanogap channel;
wherein a portion of the nanogap channel is sandwiched between the first electrode and the second electrode;
wherein at least a portion of the first electrode directly faces at least a portion of the second electrode, across the nanogap channel;
wherein the portion of the first electrode and the portion of the second electrode are exposed to an interior of the nanogap channel; and
wherein the first electrode or the second electrode comprises doped diamond, silicon carbide or a combination thereof.

2. The device of claim 1, wherein the first electrode and the second electrode are not electrically shorted.

3. The device of claim 1, wherein the nanogap channel has a height of 100 nm or less, 75 nm or less, 50 nm or less, 25 nm or less, 10 nm or less, 5 nm or less, or 1 nm or less.

4. The device of claim 1, wherein the device a plurality of electrode pairs and the nanogap channel fluidically and sequentially extends across each of the plurality of electrode pairs.

5. The device of claim 1, wherein the device has only two electrode pairs.

6. The device of claim 1, wherein the device has only three electrode pairs.

7. The device of claim 1, further comprising a bioreactor.

8. The device of claim 7, wherein the bioreactor is arranged such that all reaction products from the bioreactor flow into the nanogap channel and the electrode pair.

9. The device of claim 7, wherein the bioreactor is inside the nanogap channel.

10. The device of claim 7, wherein the bioreactor is an area with a functionalized surface.

11. The device of claim 7, wherein a molecule is immobilized to the bioreactor, wherein the molecule is selected from a group consisting of a polymerase, a nuclease, a DNA or RNA strand, and a peptide.

12. The device of claim 1, further comprising a bypass channel fluidically parallel with the nanogap channel.

13. The device of claim 1, wherein a portion of the nanogap channel sandwiched between the portion of the first electrode and the portion of the second electrode has a length to width ratio of greater than 50:1, greater than 100:1, greater than 500:1, greater than 1000:1, or greater than 2000:1.

14. A method comprising:
forming on a carrier substrate a first material layer comprising doped diamond, silicon carbide or a combination thereof;
bonding the first material layer onto an electrical circuit.

15. The method of claim 14, further comprising forming a sacrificial layer on the first material layer.

16. The method of claim 15, wherein the sacrificial layer is selected from a group consisting of Cr, TaN, W and a combination.

17. The method of claim 15, wherein the sacrificial layer has a thickness of 100 nm or less, 75 nm or less, 50 nm or less, 25 nm or less, 10 nm or less, 5 nm or less, or 1 nm or less.

18. The method of claim 15, further comprising forming on the sacrificial layer a second material layer comprising doped diamond, silicon carbide or a combination thereof.

19. The method of claim 18, further comprising patterning the second material layer to form a second electrode.

20. The method of claim 19, further comprising patterning the sacrificial layer.

21. The method of claim 20, further comprising patterning the first material layer to form a first electrode.

22. The method of claim 21, further comprising removing the sacrificial layer to form a nanogap channel.

23. The method of claim 22, wherein a portion of the nanogap channel is sandwiched between the first electrode and the second electrode.

24. The method of claim 22, wherein at least a portion of the first electrode directly faces at least a portion of the second electrode, across the nanogap channel.

25. The method of claim 24, wherein the portion of the first electrode and the portion of the second electrode are exposed to an interior of the nanogap channel.
